(19) United States
(12) Patent Application Publication
(10) Pub. No.: US 2013/0265505 A1
(43) Pub. Date: Oct. 10, 2013

(54) TELEVISION AND ELECTRONIC APPARATUS

(71) Applicant: KABUSHIKI KAISHA TOSHIBA, Tokyo (JP)

(72) Inventors: Morita HIROFUMI, Higashiyamato-shi (JP); Shigeki NISHIYAMA, Hino-shi (JP); Yuki SATO, Ome-shi (JP); Jun MORIMOTO, Yokohama-shi (JP); Yuji SASAKI, Yokohama-shi (JP); Takyua MATSUDA, Yokohama-shi (JP)

(73) Assignee: Kabushiki Kaisha Toshiba, Tokyo (JP)

(21) Appl. No.: 13/737,376

(22) Filed: Jan. 9, 2013

(30) Foreign Application Priority Data
Apr. 6, 2012 (JP) 2012-087766

(51) Int. Cl. H04N 5/64; H05K 5/00

(52) U.S. Cl. CPC H04N 5/64; H05K 5/0017
USPC 348/843; 361/679.01

(57) ABSTRACT

According to one embodiment, an electronic apparatus includes a display, a rear cover, a supporter, and a front mask. The rear cover is configured to cover a rear surface of the display. The supporter is between the display and the rear cover. The supporter is configured to support the rear surface of the display. The front mask is exposed to an outside. The front mask includes an opening and a protrusion. The opening is configured to expose a front surface of the display. The protrusion is configured to support the display. The protrusion includes a first portion and a second portion. The first portion is configured to face a side surface of the display. The second portion is configured to face a side surface of the supporter.

### CROSS-REFERENCE TO RELATED APPLICATIONS

This application is based upon and claims the benefit of priority from prior Japanese Patent Application No. 2012-087766, filed Apr. 6, 2012, the entire contents of which are incorporated herein by reference.

### FIELD

Embodiments described herein relate generally to electronic apparatuses including televisions.

### BACKGROUND

An electronic apparatus has been proposed which includes a housing having a display therein.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary front view illustrating a television according to a first embodiment;

FIG. 2 is an exemplary side view illustrating the television shown in FIG. 1;

FIG. 3 is an exemplary cross-sectional view illustrating a display unit of the television shown in FIG. 1;

FIG. 4 is an exemplary exploded cross-sectional view illustrating the display unit shown in FIG. 3;

FIG. 5 is an exemplary perspective view illustrating an electronic apparatus according to a second embodiment;

FIG. 6 is an exemplary plan view illustrating an internal structure of the electronic apparatus shown in FIG. 5;

FIG. 7 is an exemplary plan view illustrating the internal structure of the electronic apparatus shown in FIG. 5;

FIG. 8 is an exemplary cross-sectional view illustrating the electronic apparatus shown in FIG. 5;

FIG. 9 is an exemplary cross-sectional view illustrating an example of the electronic apparatus shown in FIG. 5;

FIG. 10 is an exemplary perspective view illustrating in detail an example of a portion of the rear cover shown in FIG. 9;

FIG. 11 is an exemplary perspective view illustrating in detail an example of a portion of a front mask shown in FIG. 9;

FIG. 12 is an exemplary perspective view illustrating in detail an example of another portion of the rear cover shown in FIG. 9;

FIG. 13 is an exemplary perspective view illustrating in detail an example of another portion of the front mask shown in FIG. 9;

FIG. 14 is an exemplary perspective view illustrating an example of the rear cover shown in FIG. 9;

FIG. 15 is an exemplary perspective view illustrating an example of the front mask shown in FIG. 9;

FIG. 16 is an exemplary perspective view illustrating in detail an example of still another portion of the front mask shown in FIG. 9;

FIG. 17 is an exemplary cross-sectional view illustrating a modification of the electronic apparatus shown in FIG. 9;

FIG. 18 is an exemplary cross-sectional view illustrating an electronic apparatus according to a third embodiment;

FIG. 19 is an exemplary cross-sectional view illustrating an electronic apparatus according to a fourth embodiment;

FIG. 20 is an exemplary cross-sectional view illustrating an electronic apparatus according to a fifth embodiment;

FIG. 21 is an exemplary cross-sectional view illustrating an electronic apparatus according to a sixth embodiment;

FIG. 22 is an exemplary cross-sectional view illustrating an electronic apparatus according to a seventh embodiment;

FIG. 23 is an exemplary cross-sectional view illustrating an electronic apparatus according to an eighth embodiment;

FIG. 24 is an exemplary cross-sectional view illustrating an electronic apparatus according to a ninth embodiment;

FIG. 25 is an exemplary cross-sectional view illustrating an electronic apparatus according to a tenth embodiment; and

FIG. 26 is an exemplary cross-sectional view illustrating an electronic apparatus according to an eleventh embodiment.

### DETAILED DESCRIPTION

Various embodiments will be described hereinafter with reference to the accompanying drawings.

In general, according to one embodiment, an electronic apparatus comprises a display, a rear cover, a supporter, and a front mask. The rear cover is configured to cover a rear surface of the display. The supporter is between the display and the rear cover. The supporter is configured to support the rear surface of the display. The front mask is exposed to an outside. The front mask comprises an opening and a protrusion. The opening is configured to expose a front surface of the display. The protrusion is configured to support the display. The protrusion comprises a first portion and a second portion. The first portion is configured to face a side surface of the display. The second portion is configured to face a side surface of the supporter.

Hereinafter, exemplary embodiments will be described with reference to the accompanying drawings. In the specification, for a television and an electronic apparatus, the front, rear, left, and right sides are defined on the basis of the position of the user who uses the television and the electronic apparatus (i.e., the position where the user faces a display screen). That is, the near side (i.e., the user side or the side on which the display screen is exposed) is defined as the front side, the far side (i.e., side opposite to the display screen) as viewed from the user is defined as the rear side, the left side as viewed from the user is defined as the left side, and the right side as viewed from the user is defined as the right side.

In this specification, some components are expressed by two or more terms. Those terms are just examples. Those components may be further expressed by another or other terms. And the other components which are not expressed by two or more terms may be expressed by another or other terms.

### First Embodiment

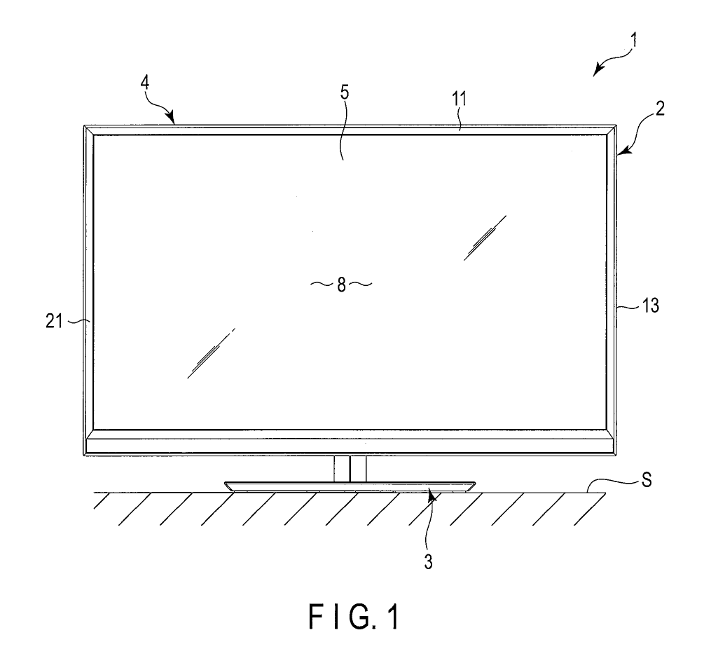

FIGS. 1 to 4 show a television 1 according to a first embodiment. The television 1 is an example of an “electronic apparatus”. The television 1 includes a display unit 2 and a stand 3 (i.e., a supporter or a table) which supports the display unit 2. The stand 3 is placed on, for example, an external mounting surface S (i.e., a mounting surface or an installation surface) and supports the display unit 2 in a rising state.

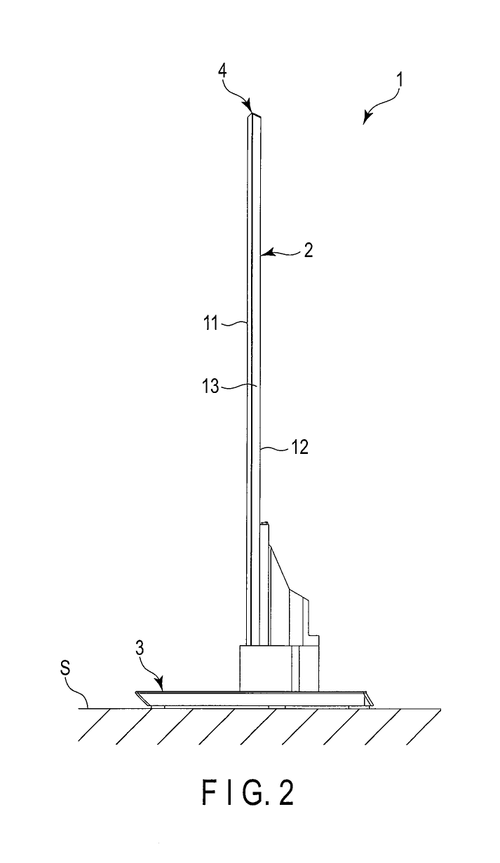

As shown in FIGS. 1 and 2, the display unit 2 includes a housing 4 having a flat box shape and a display unit 5 attached to (e.g., accommodated in) the housing 4. The display unit 5 according to this embodiment includes a display 6 and a light-permeable (i.e., light-transmitting, e.g., transparent) panel 7.

The display 6 (i.e., a display device, a display module, a display panel, a panel, a display sheet, or a sheet) includes a display screen 8 on which an image or a video is displayed. An example of the display 6 is a liquid crystal display (LCD) or an organic electro-luminescent display (OELD). The display 6 is not limited thereto, but various displays can be widely applied.

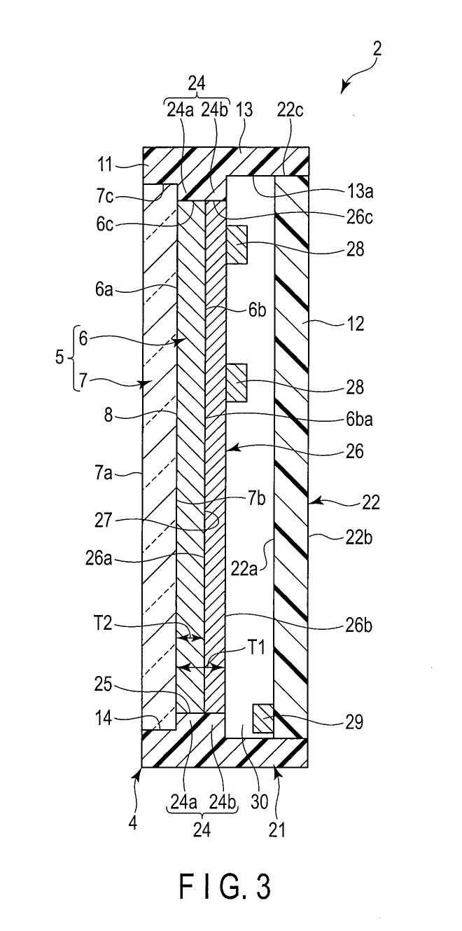

As shown in FIG. 3, the display 6 has, for example, a rectangular plate shape. The display 6 includes a front surface 6a (i.e., first surface), a rear surface 6b (i.e., a back surface or a second surface), and a side surface 6c (i.e., a circumferential surface or a third surface). The front surface 6a includes the display screen 8. The rear surface 6b is opposite to the front surface 6a and extends substantially in parallel to the front surface 6a. The side surface 6c extends in a direction intersecting (e.g., substantially perpendicular to) the front surface 6a and the rear surface 6b. The side surface 6c connects the circumferential end (i.e., the end or the edge) of the front surface 6a and the circumferential end (i.e., the end or the edge) of the rear surface 6b.

As shown in FIG. 3, the panel 7 (i.e., panel portion) faces the front surface 6a of the display 6. The size of the panel 7 is more than, for example, the size of the display 6. An example of the panel 7 is a protective panel (i.e., a protective member, a protective sheet, a sheet, or a panel) that covers the display 6. The panel 7 is made of, for example, a material with rigidity higher than that of the display 6. In this embodiment, the panel 7 overlaps the front surface 6a of the display 6 and is fixed to the front surface 6a of the display 6.

A light-permeable (e.g., transparent) adhesive portion (e.g., adhesive layer) is provided between the panel 7 and the display 6. An example of the adhesive portion is a translucent double-sided tape (e.g., Optical Clear Adhesion (OCA)). In this way, the display 6 is supported by the panel 7.

In this embodiment, the panel 7 is a touch panel provided with a touch sensor. That is, the panel 7 is an example of a sensor unit (i.e., an operation unit, an input unit, or an input receiving unit). For example, the user can input information or perform operations using the surface of the panel 7.

In this embodiment, the panel 7 functions as both a protective panel and a touch panel, but the embodiments are not limited thereto. The panel 7 may function as any one of the protective panel and the touch panel. In addition, the panel 7 may not function as the protective panel and the touch panel, but may be provided for other purposes.

As shown in FIG. 3, the panel 7 has, for example, a rectangular plate shape. The panel 7 includes a front surface 7a (i.e., first surface), a rear surface 7b (i.e., a back surface or a second surface), and a side surface 7c (i.e., a circumferential surface or a third surface). The front surface 7a is exposed to the outside of the television 1. The rear surface 7b is opposite to the front surface 7a and extends substantially in parallel to the front surface 7a. The side surface 7c extends in a direction intersecting (e.g., substantially perpendicular to) the front surface 7a and the rear surface 7b. The side surface 7c connects the circumferential end (i.e., the end or the edge) of the front surface 7a and the circumferential end (i.e., the end or the edge) of the rear surface 7b.

The front surface 7a of the panel 7 forms the front surface of the display unit 5. The rear surface 6b of the display 6 forms the rear surface of the display unit 5. Each of the side surface 7c of the panel 7 and the side surface 6c of the display 6 forms a portion of the side surface (i.e., circumferential surface) of the display unit 5.

As shown in FIGS. 1 to 3, the housing 4 includes a front wall 11 (i.e., first wall), a rear wall 12 (i.e., a back wall or a second wall), and a side wall 13 (i.e., a circumferential wall or a third wall). A portion of the front wall 11 according to this embodiment is located on a front side of the front surface 6a of the display 6.

The front wall 11 includes a first opening 14 through which the panel 7 and the front surface 6a (e.g., display screen 8) of the display 6 are exposed. The front wall 11 has a frame shape covering the side surface 7c (i.e., circumferential surface) of the panel 7. In other words, the panel 7 is accommodated in the first opening 14 and is disposed inside the first opening 14. The front surface 7a of the panel 7 is substantially flush with, for example, a surface of the front wall 11 and is substantially connected to the surface of the front wall 11.

The rear wall 12 is opposite to the front wall 11. The rear wall 12 is disposed on the rear side of the display 6 and covers the rear surface 6b of the display 6. The rear wall 12 extends substantially in parallel to the front wall 11. The side wall 13 extends in a direction intersecting (e.g., substantially perpendicular to) the front wall 11 and the rear wall 12. The side wall 13 extends in the thickness direction of the housing 4. The side wall 13 connects the front wall 11 and the rear wall 12 (i.e., the circumferential end of the rear wall 12).

As shown in FIG. 3, the housing 4 includes a front mask 21 (i.e., a front cover, a first cover, or a first member) and a rear cover 22 (i.e., a base, a second cover, or a second member). Each of the front mask 21 and the rear cover 22 is an example of a housing member, a cover, a cover portion, a supporter, a protective portion, a wall, a component, or a member.

The front mask 21 includes the front wall 11 and the side wall 13 and covers the side surface 6c of the display 6. The rear cover 22 includes the rear wall 12 and covers the rear surface 6b of the display 6. The rear cover 22 is coupled to the front mask 21. The rear cover 22 is attached to the front mask 21 to form an example of the housing 4. In this embodiment, the front mask 21 and the rear cover 22 are made of, for example, plastic, but the material forming the front mask 21 and the rear cover 22 is not limited to plastic.

Each of the front mask 21 and the rear cover 22 is an example of an external member (i.e., exterior member). Each of the front mask 21 and the rear cover 22 is exposed to the outside of the television 1 and forms a portion of the outer surface (i.e., an outward surface, a surface, or a surface exposed to the outside) of the television 1. The front mask 21 is attached to the stand 3 (i.e., external supporter) and is supported by the stand 3.

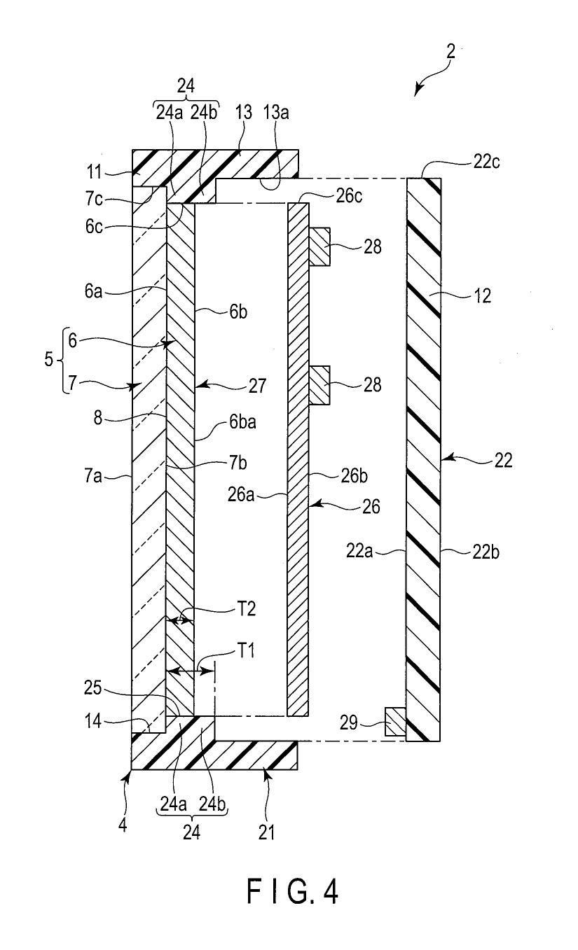

As shown in FIGS. 3 and 4, the rear cover 22 according to this embodiment has a plate shape. The rear cover 22 includes a front surface 22a (i.e., an inner surface or a first surface), a rear surface 22b (i.e., a back surface, an outer surface, or a second surface), and a side surface 22c (i.e., a circumferential surface or a third surface). The front surface 22a is exposed to the inside of the housing 4 and faces the rear surface 6b of the display 6.

The rear surface 22b is opposite to the front surface 22a and is exposed to the outside of the housing 4. The rear surface 22b extends substantially in parallel to the front surface 22a. The side surface 22c extends in a direction intersecting (e.g., substantially perpendicular to) the front surface 22a and the rear surface 22b. The side surface 22c extends in the thickness direction of the housing 4. The side surface 22c connects the circumferential end (i.e., the end or the edge) of the front surface 22a and the circumferential end (i.e., the end or the edge) of the rear surface 22b.

As shown in FIG. 3, the side wall 13 extends from the front wall 11 to the rear cover 22 (e.g., the circumferential end of the rear cover 22). The end of the side wall 13 is disposed on the side of the rear cover 22 and faces the side surface 22c of the rear cover 22 (e.g., covers the side surface 22c). Therefore, as the housing 4 is viewed from the side, the rear cover 22 is not exposed to the outside. In this way, the housing 4 with a good outward appearance is provided.

As shown in FIG. 3, the front mask 21 includes a protrusion 24 (a supporter, a protrusion, a holding portion, an attachment portion, a rib, an engaging portion, an annular portion, or a frame portion). The protrusion 24 is a portion of the front mask 21 and is integrated with the front mask 21. The protrusion 24 protrudes from the inner surface 13a of the side wall 13 toward the inside of the housing 4. The protrusion 24 protrudes from the inner surface 13a of the side wall 13 toward the side surface 6c of the display 6.

The protrusion 24 protrudes from the inner surface 13a of the side wall 13 in a direction substantially parallel to the rear surface 6b of the display 6 (i.e., a direction substantially perpendicular to the thickness direction of the housing 4). The protrusion 24 is provided in an annular shape (i.e., frame shape) along the inner surface 13a of the side wall 13. The protrusion 24 has an annular shape surrounding the side surface 6c (i.e., circumferential surface) of the display 6. The protrusion 24 has an annular shape along the circumferential end of the display 6.

The protrusion 24 continuously protrudes along the entire inner surface 13a (i.e., inner circumferential surface) of the side wall 13. In this way, the protrusion 24 defines a second opening 25 that surrounds the side surface 6c (i.e., circumferential surface) of the display 6. The second opening 25 is smaller than the first opening 14.

The protrusion 24 is away from the surface of the front wall 11 toward the rear side by, for example, a distance corresponding to or more than the thickness of the panel 7. The protrusion 24 protrudes toward the inside (i.e., center) of the housing 4 in a direction substantially parallel toward the rear surface 6b of the display 6 farther than the inner circumferential surface of the first opening 14 provided in the front wall 11. In this way, an attachment portion (i.e., an attachment surface, a mounting surface, or a mounting portion) to which the panel 7 can be attached is provided on the rear side of the first opening 14 by the protrusion 24.

The protrusion 24 faces the rear surface 7b of the circumferential end of the panel 7 and supports the circumferential end of the panel 7. The protrusion 24 supports the panel 7, thereby supporting the display 6 through the panel 7. The adhesive portion (e.g., adhesive layer) is provided between the protrusion 24 and the rear surface 7b of the panel 7. The adhesive portion is, for example, a double-sided tape. The protrusion 24 may support at least one of the panel 7 and the display 6.

As shown in FIG. 3, the protrusion 24 includes a first portion 24a (i.e., first region) and a second portion 24b (i.e., second region). The first portion 24a and the second portion 24b are aligned with and connected to each other in the thickness direction of the housing 4. The first portion 24a and the second portion 24b may be separated from each other.

The first portion 24a protrudes from the inner surface 13a of the side wall 13 toward the side surface 6c of the display 6. The first portion 24a faces the side surface 6c of the display 6. In this embodiment, the first portion 24a supports the side surface 6c of the display 6.

The term “supporting the side surface of the display” is not limited to a case in which the first portion 24a constantly contacts and supports the side surface 6c of the display 6. The term “supporting the side surface of the display” includes a case in which there is a gap between the first portion 24a and the side surface 6c of the display 6 in a normal state and the first portion 24a comes into contact with the side surface 6c of the display 6 and supports the side surface 6c of the display 6, for example, during assembly or when external force is applied.

As shown in FIG. 3, the second portion 24b extends from the first portion 24a toward the rear cover 22. That is, the second portion 24b extends from the first portion 24a toward the rear side in the thickness direction of the housing 4. The second portion 24b protrudes toward the rear side farther than the rear surface 6b of the display 6. That is, the second portion 24b protrudes toward the rear cover 22 farther than the rear surface 6b of the display 6. The second portion 24b is closer to the rear cover 22 than the rear surface 6b of the display 6. Each of the first portion 24a and the second portion 24b has an annular shape (i.e., frame shape) defining the second opening 25.

For example, when a driving board is provided and the rear surface 6b of the display 6 is uneven, the term “protruding toward the rear cover farther than the rear surface of the display” means protruding toward the rear cover 22 farther than the recess (i.e., a portion closest to the front surface 6a of the display) of the rear surface 6b of the display 6.

Similarly, the term “portion closer to the rear cover than the rear surface of the display” means a portion closer to the rear cover 22 than the recess (i.e., the portion closest to the front surface 6a of the display) of the rear surface 6b of the display 6. In the specification, when the position of the rear surface 6b of the display 6 (or the display unit 5) is used as a reference position, the recess of the rear surface 6b of the display 6 (i.e., a portion closest to the front surface 6a of the display) is used as a reference portion.

The thickness T1 (e.g., the sum of the thickness of the first portion 24a and the thickness of the second portion 24b) of the protrusion 24 is more than the thickness T2 of the display 6. In other words, the thickness T2 of the display 6 is less than the thickness T1 of the protrusion 24. The display 6 is inserted (e.g., accommodated) into the second opening 25 and is disposed inside the second opening 25. The display 6 is within the thickness T1 of the protrusion 24.

As shown in FIG. 3, in the television 1, a supporter 26 (i.e., a supporting member, a reinforcing portion, a reinforcing member, a middle plate, a middle frame, a middle cover, a plate, a plate portion, a metal portion, a member, or a component) is provided between the display 6 and the rear cover 22. In this embodiment, the supporter 26 is, for example, a metal plate (i.e., a plate member, a plate, or a sheet) and is provided separately from the housing 4. The supporter 26 may be made of plastic or other materials.

As shown in FIG. 3, at least a portion of the supporter 26 is inserted into the second opening 25 and is disposed inside the second opening 25. In other words, a recess 27 is formed by the rear surface 6b of the display 6 and the inner circumferential surface of the second portion 24b of the protrusion 24. The supporter 26 is arranged in the recess 27.

The supporter 26 faces at least a central portion 6ba (i.e., a central region, a center, a bent portion, or a deformed portion) of the rear surface 6b of the display 6. The supporter 26 supports at least the central portion 6ba of the rear surface 6b of the display 6. In this embodiment, the supporter 26 is formed with a size substantially equal to or more than that of the rear surface 6b of the display 6 and supports the entire rear surface 6b of the display 6. For example, the supporter 26 may support only a portion of the rear surface 6b of the display 6. In other words, the supporter 26 may support only the region other than the central portion 6ba.

The term “supporting the rear surface of the display” is not limited to a case in which the supporter 26 constantly contacts and supports the rear surface 6b of the display 6. The term “supporting the rear surface of the display” includes a case in which there is a gap between the supporter 26 and the rear surface 6b of the display 6 in a normal state and the supporter 26 comes into contact with the rear surface 6b of the display 6 and supports the rear surface 6b of the display 6, for example, during assembly or when external force is applied.

The supporter 26 includes a front surface 26a (i.e., first surface), a rear surface 26b (i.e., a back surface or a second surface), and a side surface 26c (i.e., a circumferential surface or a third surface). The front surface 26a faces the rear surface 6b of the display 6. The front surface 26a extends substantially in parallel to the rear surface 6b of the display 6. The front surface 26a is, for example, planar (i.e., flat) and even. The rear surface 26b is opposite to the front surface 26a. The rear surface 26b extends substantially in parallel to the front surface 26a. The side surface 26c extends in a direction intersecting (e.g., substantially perpendicular to) the front surface 26a and the rear surface 26b. The side surface 26c connects the circumferential end (i.e., the end or the edge) of the front surface 26a and the circumferential end (i.e., the end or the edge) of the rear surface 26b.

As shown in FIG. 3, a part of the second portion 24b is closer to the rear cover 22 than a part (e.g., the front surface 26a) of the supporter 26. That is, the second portion 24b protrudes toward the rear cover 22 farther than the part of the supporter 26. The second portion 24b of the protrusion 24 faces the side surface 26c of the supporter 26. The second portion 24b of the protrusion 24 comes into contact with the side surface 26c of the supporter 26 and supports the supporter 26.

The term “supporting the side surface of the supporter” is not limited to a case in which the protrusion 24 constantly contacts and supports the side surface 26c of the supporter 26. The “supporting the side surface of the supporter” includes a case in which there is a gap between the protrusion 24 and the side surface 26c of the supporter 26 in a normal state and the protrusion 24 comes into contact with the side surface 26c of the supporter 26 and supports the side surface 26c of the supporter 26, for example, during assembly or when external force is applied.

In this embodiment, the supporter 26 is supported by the protrusion 24, but the embodiments are not limited thereto. The supporter 26 may be supported by, for example, other portions of the housing 4, or a component or a member provided in the housing 4.

As shown in FIG. 3, the television 1 includes a first component 28 (i.e., a first electronic component or a first functional component) and a second component 29 (i.e., a second electronic component or a second functional component). Each of the first and second components 28 and 29 is, for example, a circuit board, a speaker, a microphone, or a connector, but is not limited thereto. The first component 28 is attached to, for example, the rear surface 26b of the supporter 26.

As shown in FIG. 3, an accommodating portion 30 (i.e., an accommodating space, a space, an accommodating region, or a region) in which the second component 29 is accommodated is provided between the protrusion 24 and the rear cover 22. The second component 29 is attached to, for example, the rear cover 22 or the protrusion 24 and is disposed between the protrusion 24 and the rear cover 22.

According to this structure, it is possible to improve the protection of the display unit 5 and the solidity of the housing 4.

In this embodiment, the protrusion 24 of the front mask 21 includes the first portion 24a that faces the side surface of the display unit 5 and the second portion 24b that protrudes toward the rear cover 22 farther than the first portion 24a so as to be closer to the rear cover 22 than the rear surface of the display unit 5 and supports the display unit 5. According to this structure, the protrusion 24 makes it possible to improve the solidity of the housing 4 around the display unit 5. Therefore, it is possible to improve the protection of the display unit 5.

In this embodiment, the supporter 26 is provided to support the rear surface of the display unit 5. Therefore, for example, the supporter 26 can receive a portion of the pressing force applied to the front surface of the display unit 5 when the user performs an operation. In this way, it is possible to suppress the display unit 5 from being bent and thus further improve the protection of the display unit 5.

In this embodiment, at least a part of the supporter 26 is disposed in the second opening 25 which is defined by the protrusion 24 supporting the display unit 5. That is, the internal region of a housing structure supporting the display unit 5 is used to dispose the supporter 26. According to this structure, it is possible to achieve high-density mounting and reduce the thickness of the housing 4.

In this embodiment, the supporter 26 is supported by a part of the protrusion 24 supporting the display unit 5. Therefore, it is possible to reduce a special structure for supporting the supporter 26 or the special structure may not be provided. In this way, it is possible to further reduce the thickness or size of the housing 4.

In this embodiment, the first component 28 is attached to the rear surface 26b of the supporter 26. Since the supporter 26 has rigidity, it is easy to mount components on the supporter 26. Therefore, when the supporter 26 is used to mount the first component 28, the mounting of the first component 28 is likely to be stabilized. As a result, it is possible to improve the assemblability of the television 1.

In this embodiment, the accommodating portion 30 in which the second component 29 can be accommodated is provided between the protrusion 24 and the rear cover 22. According to this structure, it is possible to mount components between the protrusion 24 and the rear cover 22. This structure can contribute to achieving high-density mounting in the television 1 and reducing the thickness and size of the television 1.

### Second Embodiment

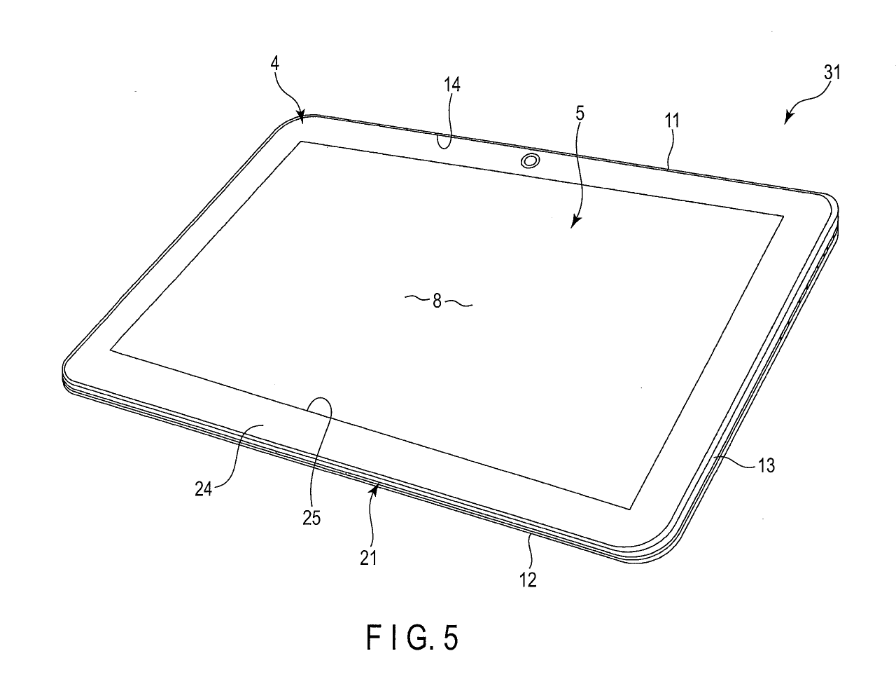

Next, an electronic apparatus 31 according to a second embodiment will be described with reference to FIGS. 5 to 8. In the second embodiment, components having the same or similar functions as those in the first embodiment are denoted by the same reference numerals and the description thereof will not be repeated. Structures other than the following structures are the same as those in the first embodiment. The term “television” in the first embodiment is replaced with an “electronic apparatus”.

As shown in FIG. 5, an electronic apparatus 31 according to this embodiment is, for example, a slate portable computer (i.e., a slate PC or a tablet). The electronic apparatus to which the structures according to all of the embodiments and modifications described in the specification can be applied is not limited to the above-mentioned example. All of the embodiments and modifications described in the specification can be widely applied to various electronic apparatuses, such as notebook portable computers (notebook PCs), televisions, mobile phones (including smart phones), and game machines.

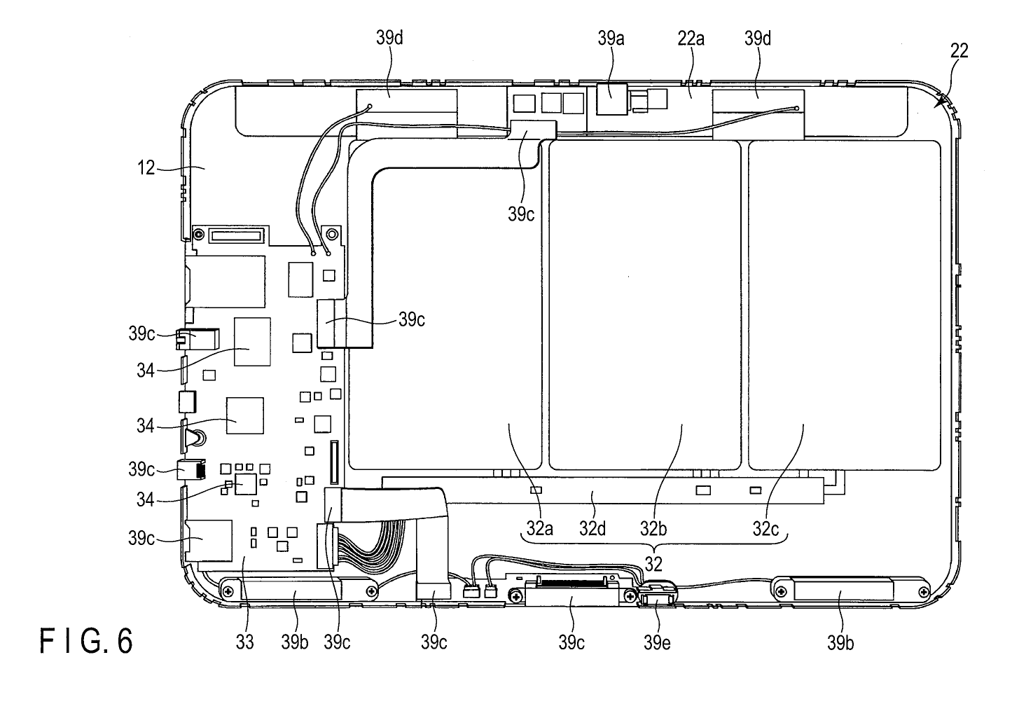

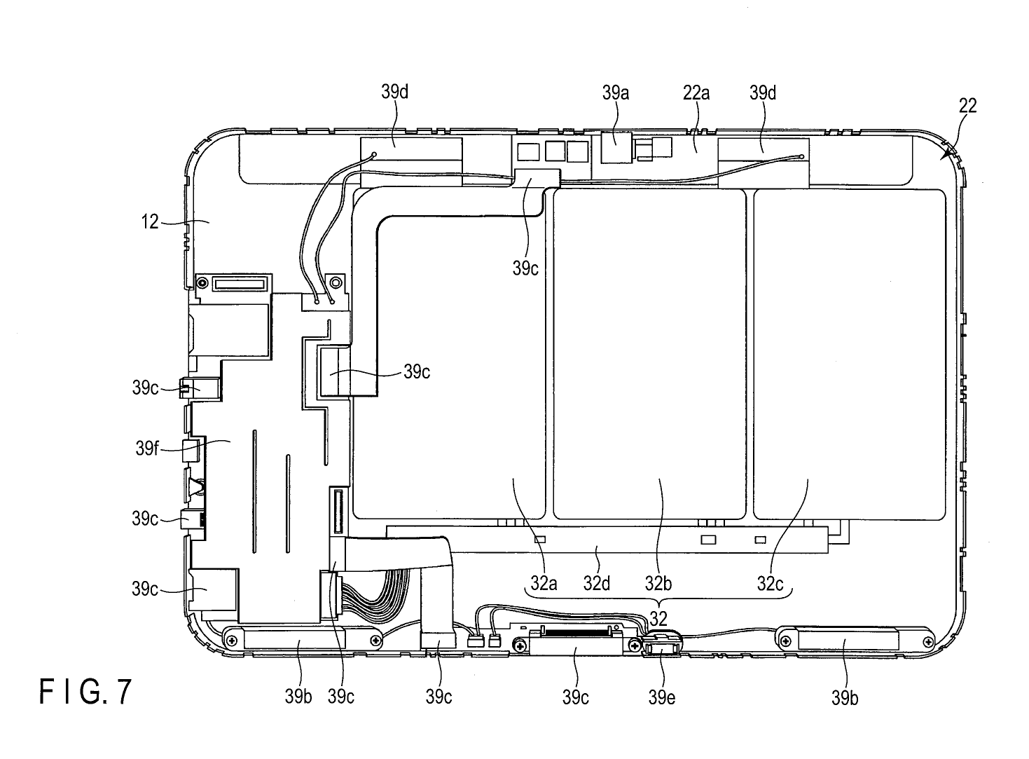

As shown in FIG. 5, the electronic apparatus 31 includes a housing 4 with a flat box shape. Similarly to the first embodiment, a display unit 5 is attached to (e.g., accommodated in) the housing 4. As shown in FIGS. 6 and 7, a battery 32 (e.g., a cell) and a circuit board 33 (i.e., a printed circuit board, a control board, or a board) are accommodated in the housing 4.

As shown in FIG. 6, in this embodiment, the battery 32 includes a plurality of cells 32a, 32b, and 32c and a circuit board 32d. The plurality of cells 32a, 32b, and 32c are electrically connected in series or parallel to each other. The electrodes of the cells 32a, 32b, and 32c are electrically connected to the circuit board 32d. As such, since the plurality of cells 32a, 32b, and 32c are integrated with each other, the time and effort required for manufacture and manufacturing costs are reduced, as compared to a case in which the cells 32a, 32b, and 32c are independently assembled.

Each of the cells 32a, 32b, and 32c is an independent electric cell including a chamber (i.e., accommodating portion) in which, for example, an electrolyte (i.e., electrolytic solution), an electrode, and a separator are accommodated (i.e., provided). Each of the cells 32a, 32b, and 32c has a rectangular shape (i.e., a plate shape, a square plate shape, or a card shape) which is thin and flat in the thickness direction of the housing 4.

In this embodiment, the outermost layer of each of the cells 32a, 32b, and 32c is a sheet-shaped sheath (i.e., a layer or a film) with an insulating property and flexibility and a hard case (i.e., shell) is not provided. According to this embodiment, it is possible to reduce the size (e.g., thickness) and weight of the battery 32 (e.g., cells 32a, 32b, and 32c) due to the absence of the case. In this way, it is possible to reduce the size, thickness, and weight of the housing 4 (i.e., electronic apparatus 31).

A plurality of components 34 (i.e., elements, electronic components, or electric components) including, for example, a central processing unit (CPU) are provided on the circuit board 33. The components 34 include a heat-generating body. As shown in FIG. 6, the battery 32 and the circuit board 33 do not overlap each other in the thickness direction of the housing 4 and are arranged along a rear wall 12 of the housing 4. Therefore, it is possible to reduce the thickness of the housing 4, as compared to a case in which the battery 32 and the circuit board 33 overlap each other in the thickness direction of the housing 4.

As shown in FIG. 6, the housing 4 further includes a camera 39a (i.e., a camera module, a camera unit, a camera assembly, or an imaging device), a speaker 39b (i.e., a speaker module, a speaker unit, a speaker assembly, or a sound output device), a connector 39c (i.e., a connector module, a connector unit, a connector assembly, or a connector device), an antenna 39d (i.e., an antenna module, an antenna unit, an antenna assembly, or an antenna device), and a vibrator 39e (i.e., vibration generating unit). An example of the vibrator 39e is a motor in which an eccentric weight is attached to a rotating shaft.

As shown in FIG. 7, a heat dissipating portion 39f is attached to the circuit board 33. An example of the heat dissipating portion 39f is a plate made of a material (e.g., a metal material, such as an aluminum alloy) with high thermal conductivity. A thermally conductive sheet is provided between the heat dissipating portion 39f and the component 34. In this way, a portion of the heat generated from the component 34 is dissipated by the heat dissipating portion 39f.

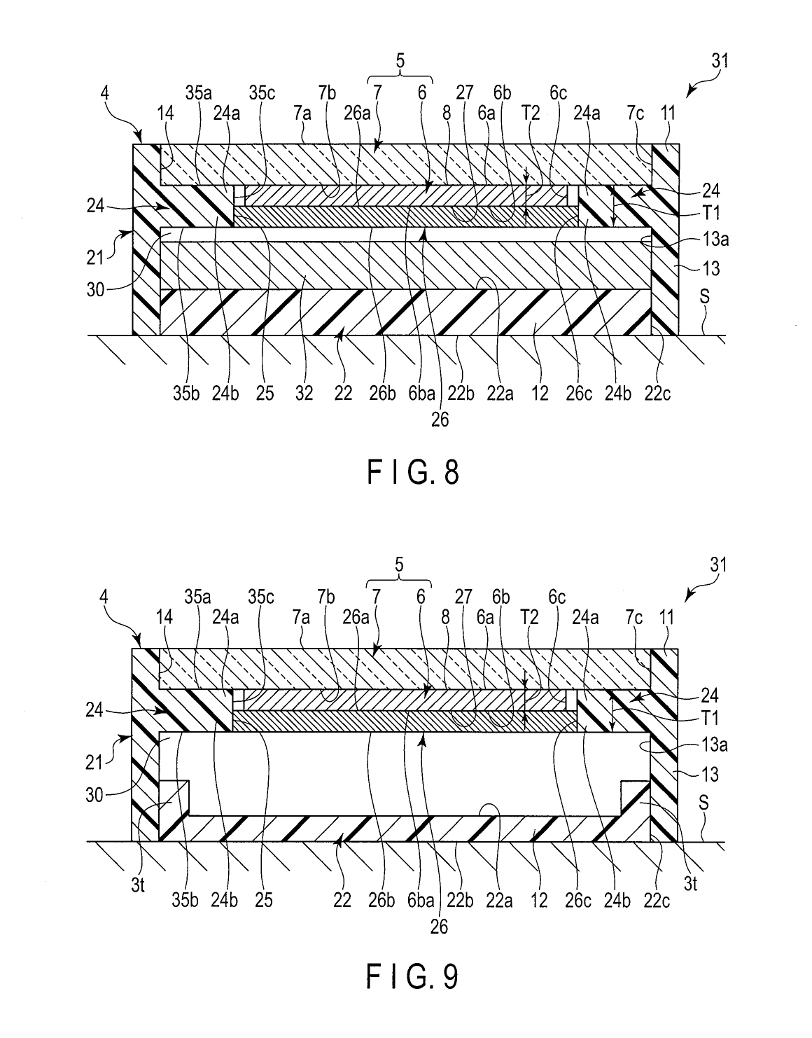

As shown in FIG. 8, in this embodiment, similarly to the first embodiment, the housing 4 includes a front mask 21 and a rear cover 22. The front mask 21 comes into contact with, for example, an external mounting surface S (i.e., a mounting surface or an installation surface) and is supported by the external mounting surface S. The external mounting surface S is an example of an “external supporter”.

As shown in FIG. 9, a protrusion 24 includes a first surface 35a, a second surface 35b, and a third surface 35c. The first surface 35a and the second surface 35b are substantially parallel to a front surface 6a of a display 6. The first surface 35a faces the outside (e.g., front side) of the housing 4. The first surface 35a faces a rear surface 7b of the circumferential end of a panel 7.

The second surface 35b is opposite to the first surface 35a. The second surface 35b faces the inside of the housing 4. The second surface 35b faces a rear cover 22. The third surface 35c extends in a direction intersecting (e.g., substantially perpendicular to) the first surface 35a and the second surface 35b. The third surface 35c extends in the thickness direction of the housing 4. The third surface 35c extends between the first surface 35a and the second surface 35b. The third surface 35c faces a side surface 6c of the display 6.

In this embodiment, the panel 7 is fixed to the first surface 35a of the protrusion 24. A first adhesive portion (i.e., first adhesive layer) is provided between the panel 7 and the first surface 35a of the protrusion 24. The first adhesive portion is, for example, a double-sided tape. Similarly to the first embodiment, the display 6 is fixed to the rear surface 7b of the panel 7. A second adhesive portion (i.e., second adhesive layer) is provided between the display 6 and the panel 7. The second adhesive portion is, for example, a translucent double-sided tape (e.g., Optical Clear Adhesion (OCA)). In this way, the display 6 is attached to the rear surface 7b of the panel 7.

The thickness of each of the first and second adhesive portions is, for example, 0.15 mm. The first and second adhesive portions have substantially the same thickness. In this way, the display 6 is disposed inside a second opening 25.

The display 6 according to this embodiment is, for example, a very thin sheet display. An example of the display 6 is a plastic organic EL display using a plastic board and has flexibility (i.e., bendability). For example, the thickness T2 of the display 6 is about 0.25 mm, but is not limited thereto.

The front mask 21 is made of, for example, a resin or metal. The front mask 21 made of a resin or metal is manufactured by, for example, injection molding, die-casting, or milling. In these manufacturing methods, there is a limitation in reducing the thickness T1 of the protrusion 24 and it is difficult to reduce the thickness T1 of the protrusion 24 to be less than about 0.4 mm. In addition, in order to ensure the strength of the protrusion 24, the thickness of the protrusion 24 needs to be equal to or more than a predetermined value.

Therefore, in this embodiment, the thickness T1 of the protrusion 24 is more than the thickness T2 of the display 6. Therefore, similarly to the first embodiment, the protrusion 24 includes a first portion 24a (i.e., first region) facing the side surface of the display 6 and a second portion 24b (i.e., second region) that is closer to the rear cover 22 than the rear surface 6b of the display 6.

The first portion 24a protrudes from an inner surface 13a of a side wall 13 toward the side surface 6c of the display 6. The first portion 24a faces the side surface 6c of the display 6. The second portion 24b protrudes from the first portion 24a toward the rear cover 22 so as to be closer to the rear cover 22 than the rear surface 6b of the display 6. The second portion 24b is closer to the rear cover 22 than the rear surface 6b of the display 6. The second portion 24b protrudes toward the rear cover 22 farther than a part (e.g., the front surface 26a) of the supporter 26. The display 6 is inserted into (e.g., accommodated in) the second opening 25 and is disposed inside the second opening 25. The display 6 is within the range of the thickness T1 of the protrusion 24.

Next, an example of the connection structure (i.e., the fitting structure or the coupling structure) between the front mask 21 and the rear cover 22 according to this embodiment will be described with reference to FIGS. 9 to 16. The connection structure is not limited to this embodiment, but can be applied to all of the embodiments and modifications described in the specification.

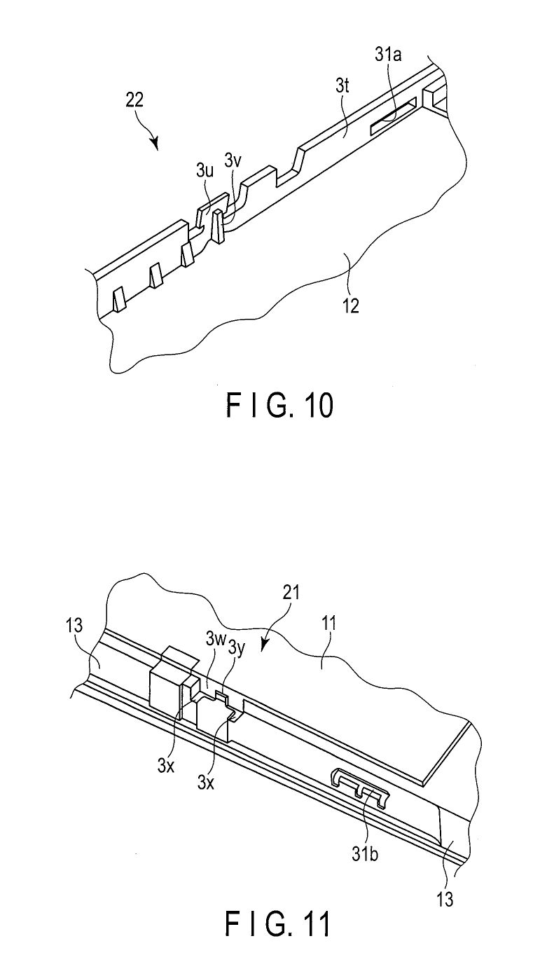

As shown in FIG. 9, the rear cover 22 includes a protrusion 3t (i.e., projection). The protrusion 3t protrudes from the rear wall 12 along the inner surface 13a of the side wall 13. As shown in FIG. 10, an engaging portion 31a (i.e., first engaging portion) is provided in the protrusion 3t. As shown in FIG. 11, an engaging portion 31b (i.e., second engaging portion) is provided in the side wall 13 of the front mask 21. The engaging portion 31a and the engaging portion 31b are engaged with each other in the thickness direction of the housing 4. In this embodiment, the engaging portion 31a is, for example, a through hole and the engaging portion 31b is, for example, a claw portion (i.e., a protrusion or a projection). The engaging portion 31a and the engaging portion 31b are engaged with each other to couple the front mask 21 and the rear cover 22. As such, in this embodiment, for example, the front mask 21 and the rear cover 22 are coupled to each other by a relatively simple structure.

As shown in FIG. 10, the rear cover 22 includes a protrusion 3u (i.e., first protrusion). The protrusion 3u protrudes from the rear wall 12 along the inner surface 13a of the side wall 13. A rib 3v (i.e., protrusion) is provided so as to protrude from the protrusion 3u to the inside of the housing 4.

As shown in FIG. 11, the front mask 21 includes a protrusion 3w (i.e., a second protrusion or a wall portion). The protrusion 3w protrudes from the front wall 11 toward the rear wall 12 such that the protrusion 3u is interposed between the protrusion 3w and the side wall 13 when assembly is completed. That is, the protrusion 3w protrudes such that a gap (e.g., a gap that is slightly more than the thickness of the protrusion 3u) capable of accommodating the protrusion 3u is formed between the protrusion 3w and the side wall 13.

The front mask 21 includes two protrusions 3x (i.e., third protrusions or wall portions) which protrude from the front wall 11 toward the rear wall 12 so as to be fitted to the protrusion 3u in a direction intersecting the thickness direction of the housing 4 (e.g., a direction along the side wall 13). That is, the two protrusions 3x protrude such that a gap (for example, a gap that is slightly more than the width of the protrusion 3u) capable of accommodating the protrusion 3u is formed therebetween.

In this embodiment, for example, with the front mask 21 coupled to the rear cover 22, the protrusion 3u is interposed between the side wall 13 and the protrusion 3w and is also interposed between the two protrusions 3x in a direction different from the direction in which it is interposed between the side wall 13 and the protrusion 3w.

As shown in FIG. 11, the protrusions 3w and 3x (e.g., wall portions) are connected to each other in a C-shape and are also connected to the side wall 13. That is, an accommodating portion with a cylindrical shape (e.g., a square cylindrical shape or an annular shape) is formed by the side wall 13 and the protrusions 3w and 3x.

According to this structure, in this embodiment, for example, the movement of the protrusion 3u of the rear cover 22 relative to the front mask 21 in the thickness direction of the side wall 13 or the direction along the side wall 13 is regulated. Therefore, according to this embodiment, for example, the separation between the contact edges of the front mask 21 and the rear cover 22 due to external force is reduced by a relatively simple structure. A cutout portion 3y (i.e., recess) in which the rib 3v is accommodated is provided in the protrusion 3w when assembly is completed. Therefore, the edge of the cutout portion 3y in the protrusion 3w also functions as a third protrusion, similarly to the protrusion 3x.

In this embodiment, for example, as shown in FIGS. 12 and 13, the protrusion 3u (i.e., first protrusion), the rib 3v, the protrusion 3w (i.e., second protrusion), and the protrusion 3x (i.e., third protrusion) are provided at four corners 3j of the housing 4. Therefore, according to this embodiment, for example, the front mask 21 and the rear cover 22 are less likely to be separated from each other at the corners 3j of the housing 4.

In this embodiment, for example, as shown in FIG. 12, the rear wall 12 includes a wall portion 30e that protrudes from the rear wall 12 toward the front wall 11. The protrusion 3u is connected to the wall portion 30e while being curved in an arc shape along the edge of the corner 3j of the rear wall 12. Therefore, according to this embodiment, for example, it is possible to further improve the rigidity and strength of the protrusion 3u. A protrusion 30f which extends in an arc shape in parallel to the wall portion 30e and protrudes toward the front wall 11 is provided at a position where it is away from the wall portion 30e toward the center of the rear wall 12, that is, from the corner 3j or the end of the rear wall 12 to the center of the rear wall 12.

In addition, a protrusion 30g (i.e., a rib or a second rib) is provided on the rear wall 12 so as to extend between the protrusion 30f (i.e., a rib or a first rib) and the wall portion 30e. Therefore, according to this embodiment, for example, it is possible to further improve the rigidity and strength of the protrusion 3u at the corner 3j to which external force is more likely to be applied than other portions when the electronic apparatus 31 drops.

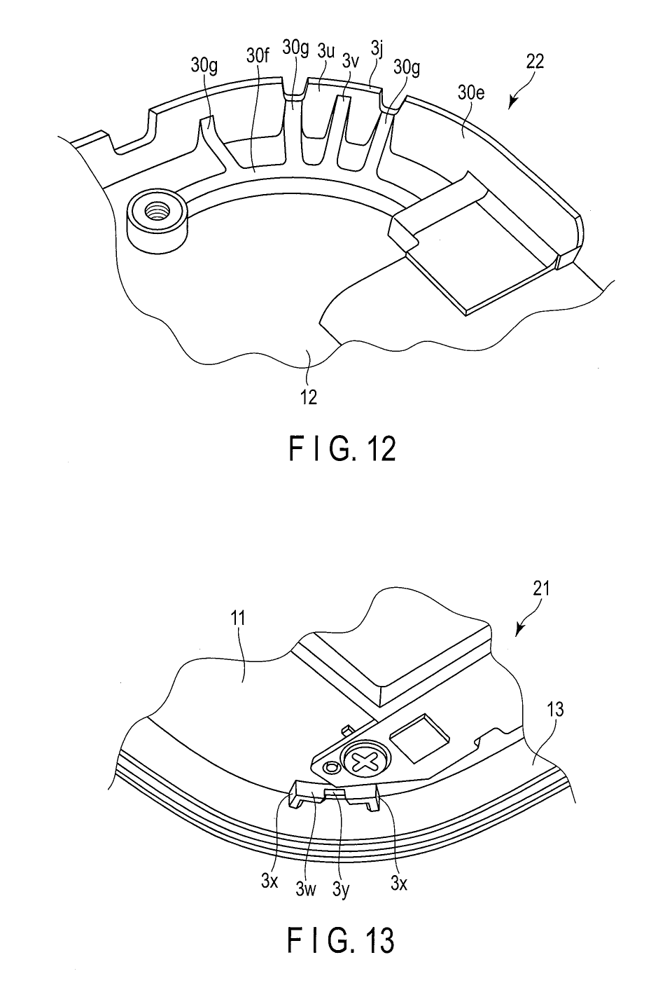

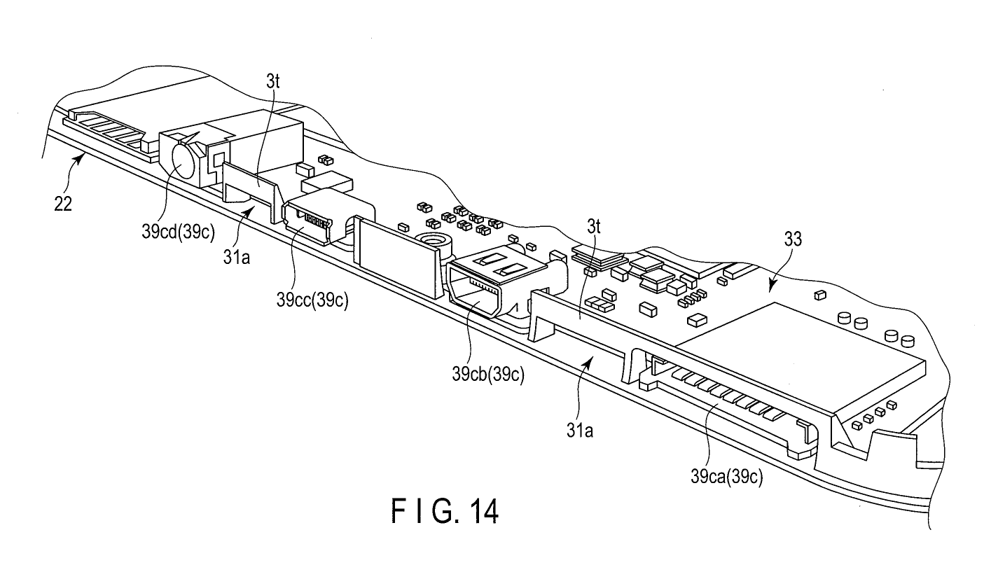

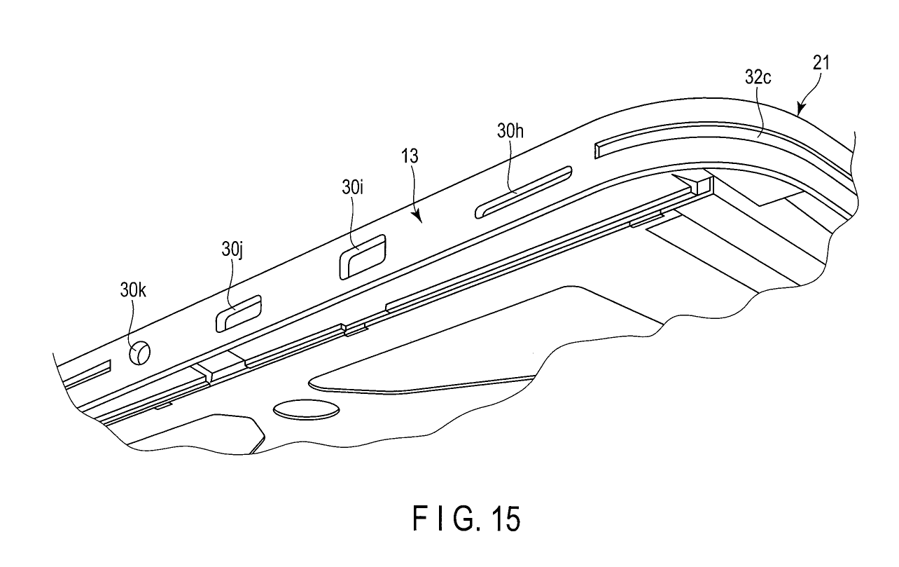

In this embodiment, for example, as shown in FIG. 14, connectors 39ca to 39cd are provided on the rear cover 21 so as to be arranged in a line along the edge of the rear cover 21. As shown in FIG. 15, openings 30h to 30k through which the connectors 39ca to 39cd are exposed to the outside of the housing 4 are provided as through holes in the side wall 13. Therefore, according to this embodiment, the rigidity and strength of the side wall 13 can be improved, as compared to, for example, a case in which the openings 30h to 30k are provided as notches.

In FIG. 14, the connector 39ca is a connector for a card into which a card is removably inserted (e.g., connected or held). The connectors 39cb to 39cd are connectors into which other connectors are removably inserted (e.g., connected or held). The terminals (i.e., protrusions, supporters, leg portions, or protrusions) of the connectors 39cb and 39cc do not pass in the thickness direction of the board 33, but extend to the middle of the board 33 in the thickness direction.

Therefore, for example, the terminals of the connectors 39cb and 39cc do not hinder the adhesion (e.g., close adhesion) between the board 33 and the rear wall 12. When the height of, for example, (e.g., the openings of) the connectors 39cb and 39cc from the board 33 is appropriately set, the connectors 39cb and 39cc and a member 32c which is provided at the intermediate position of the side wall 13 can be arranged in a direction along the side wall 13 (e.g., close to the side wall 13).

Protrusions 3t are provided between the connector 39ca and the connector 39cb and between the connector 39cc and the connector 39cd. An engaging portion 31a is provided in the protrusion 3t. The area of the engaging portion 31a serving as a through hole is gradually increased toward the opening side (e.g., the exit side or the opening end side). That is, in the engaging portion 31a, the distance from the center line of the through hole to a side surface (e.g., an inner surface, an inner circumferential surface, or a cylinder inner surface) is increased toward the exit-side end.

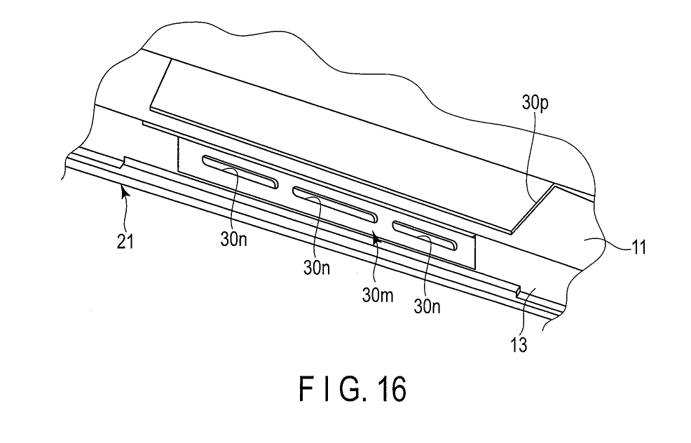

In this embodiment, for example, as shown in FIG. 16, a member 30m that extends along the end of the front mask 21 is provided on the side wall 13 of the front mask 21. The member 30m is made of a material (e.g., a metal material) harder than that forming the front mask 21. Therefore, according to this embodiment, for example, it is possible to improve the rigidity and strength of the side wall 13.

The member 30m shown in FIG. 16 faces the speaker module 39b and includes an opening 30n. The opening 30n makes it easy to output sounds from the speaker module 39b to the outside of the housing 4. That is, the member 30m is an example of a cover of the speaker module 39b. In addition, a cutout portion 30p in which the speaker module 39b is accommodated is provided in the front wall 11 of the front mask 21.

Therefore, according to this embodiment, for example, the member 30m can reinforce a portion which has lower rigidity or strength than a position without the cutout portion 30p due to the cutout portion 30p.

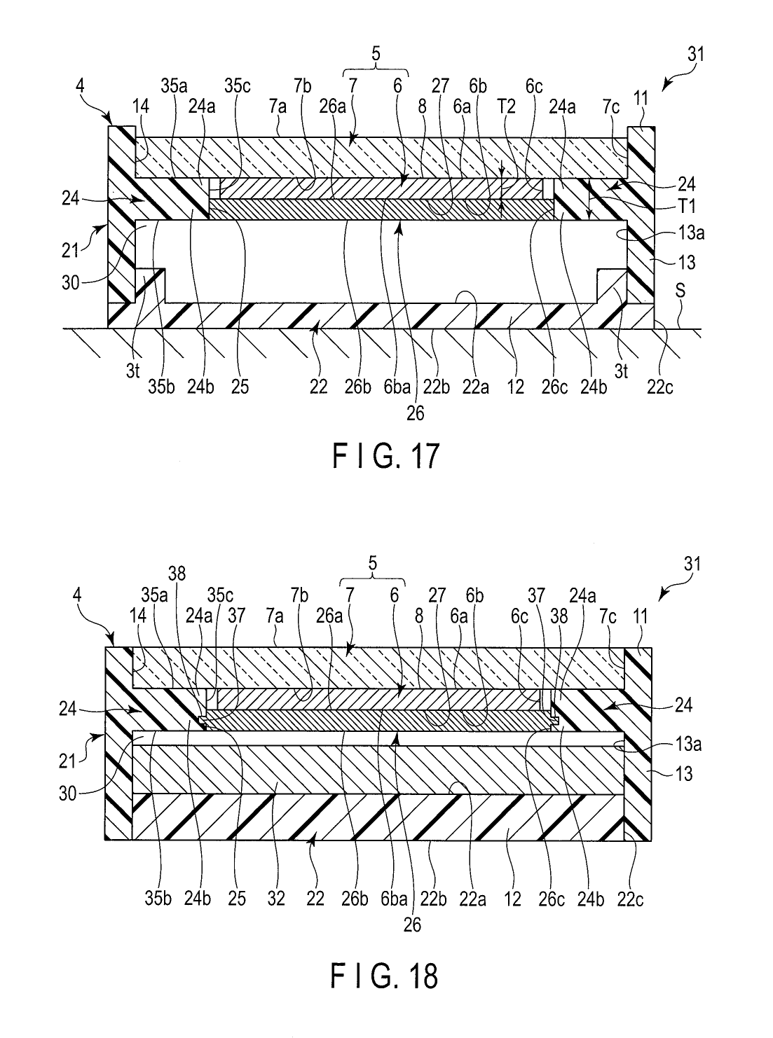

Next, a housing 4 according to a modification will be described with reference to FIG. 17. As shown in FIG. 17, in this modification, the front wall 11 of the front mask 21 protrudes from the front surface 7a of the panel 7. In this case, the panel 7 or the display 6 can be protected by the front wall 11. In both this modification and the above-described embodiment, as shown in FIG. 17, the side surface 22c of the rear cover 22 may not be covered with the front mask 21.

According to this structure, similarly to the first embodiment, it is possible to improve the protection of the display 6 and the solidity of the housing 4. Since the protrusion 24 thicker than the display 6 is provided, it is possible to further improve the solidity of the housing 4.

### Third Embodiment

Next, an electronic apparatus 31 according to a third embodiment will be described with reference to FIG. 18. In the third embodiment, components having the same or similar functions as those in the first and second embodiments are denoted by the same reference numerals and the description thereof will not be repeated. Structures other than the following structures are the same as those in the second embodiment.

As shown in FIG. 18, in this embodiment, a side surface 26c of a supporter 26 includes a first engaging portion 37 (i.e., a first coupling portion or a first connection portion). The first engaging portion 37 is, for example, a projection which protrudes toward a second portion 24b of a protrusion 24, but may be a recess. The second portion 24b of the protrusion 24 includes a second engaging portion 38 (i.e., a second coupling portion or a second connection portion) which is fitted to the first engaging portion 37. The second engaging portion 38 is, for example, a recess into which the projection, which is the first engaging portion 37, is inserted, but may be a projection which protrudes toward the supporter 26.

In this embodiment, a front mask 21 and the supporter 26 are integrally formed by, for example, insert molding. That is, with the supporter 26 with the first engaging portion 37 being set in a mold, the front mask 21 is formed by injection molding. In this way, the front mask 21 made of plastic and the supporter 26 made of metal are integrally formed.

According to this structure, similarly to the first embodiment, it is possible to improve the protection of the display 6 and the solidity of the housing 4. In addition, in this embodiment, the front mask 21 and the supporter 26 are integrally formed. According to this structure, the supporter 26 can be stably supported by the protrusion 24. Insert molding makes it unnecessary to attach a fixing member, such as a screw, and makes it possible to reduce the thickness of the electronic apparatus 31.

### Fourth Embodiment

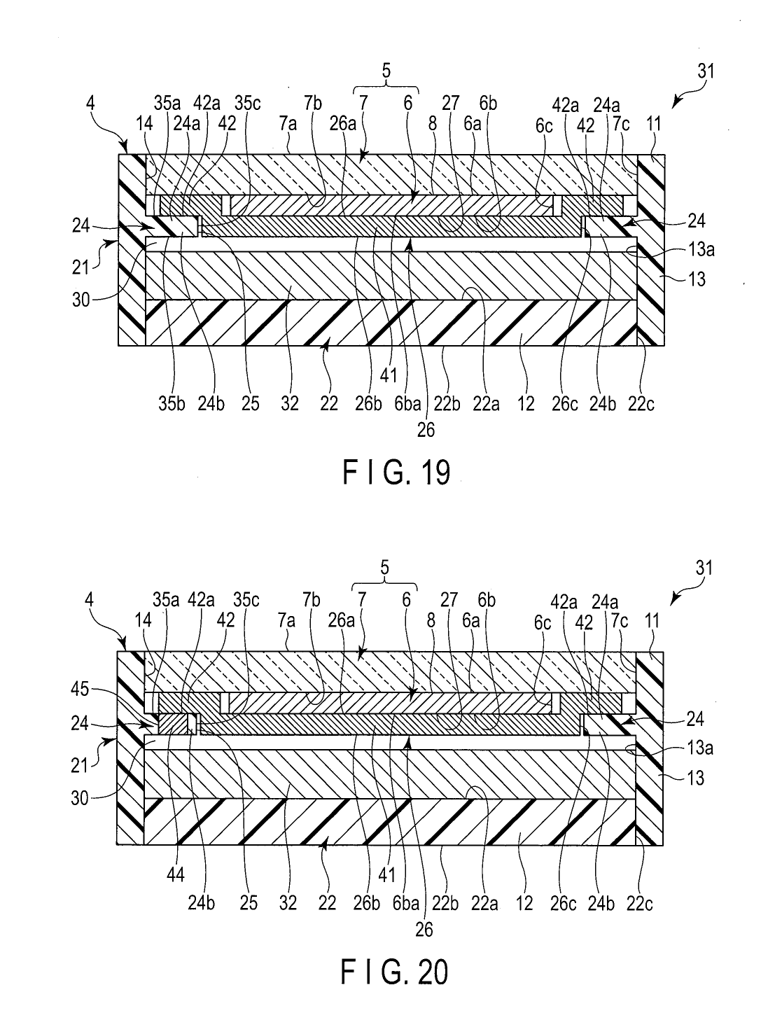

Next, an electronic apparatus 31 according to a fourth embodiment will be described with reference to FIG. 19. In the fourth embodiment, components having the same or similar functions as those in the first to third embodiments are denoted by the same reference numerals and the description thereof will not be repeated. Structures other than the following structures are the same as those in the second embodiment.

As shown in FIG. 19, in this embodiment, a protrusion 24 is provided on the rear side of a front surface 6a of a display 6. The protrusion 24 protrudes from the inner surface of a side wall 13 toward the inside of the housing 4 in a direction substantially parallel to a rear surface 6b of the display 6.

A supporter 26 includes a first portion 41 and a second portion 42. The first portion 41 faces at least a central portion 6ba of the rear surface 6b of the display 6 and supports at least the central portion 6ba of the rear surface 6b of the display 6. The first portion 41 is, for example, a plate portion which is substantially parallel to the rear surface 6b of the display 6. At least a part of the first portion 41 is inserted into a second opening 25 and is disposed inside the second opening 25.

The second portion 42 (e.g., an engaging portion, a holding portion, an attachment portion, or a fixing portion) has a level different from that of the first portion 41 and is disposed in front of the first portion 41. The second portion 42 protrudes (e.g., rises) from the first portion 41 and a part of the second portion 42 faces a side surface 6c of the display 6. The second portion 42 extends substantially in parallel to the rear surface 6b of the display 6 on the side of the display 6. The second portion 42 extends toward an inner surface 13a of the side wall 13 of the housing 4 on the side of the display 6.

The second portion 42 is disposed between the circumferential end of the panel 7 and the protrusion 24. Specifically, the second portion 42 is disposed between a rear surface 7b of the circumferential end of the panel 7 and a first surface 35a of the protrusion 24. The second portion 42 is interposed between the panel 7 and the protrusion 24. The second portion 42 is fixed to, for example, the protrusion 24. In this way, the supporter 26 is supported by the protrusion 24. The panel 7 is fixed to, for example, the second portion 42.

According to this structure, similarly to the first embodiment, it is possible to improve the protection of the display 6 and the solidity of the housing 4. In addition, in this embodiment, the supporter 26 includes an engaging portion (i.e., second portion 42) provided between the panel 7 and the protrusion 24. According to this structure, the protrusion 24 can stably support the supporter 26. In this way, it is possible to further improve the protection of the display 6.

### Fifth Embodiment

Next, an electronic apparatus 31 according to a fifth embodiment will be described with reference to FIG. 20. In the fifth embodiment, components having the same or similar functions as those in the first to fourth embodiments are denoted by the same reference numerals and the description thereof will not be repeated. Structures other than the following structures are the same as those in the third embodiment.

As shown in FIG. 20, in this embodiment, the electronic apparatus 31 includes a component 44. The component 44 is attached to a second portion 42 of a supporter 26. The second portion 42 includes an attachment surface (i.e., supporting surface) 42a that faces a rear cover 22. The component 44 is attached to the attachment surface 42a of the second portion 42 and faces the rear cover 22. The component 44 is disposed between the second portion 42 and the rear cover 22.

A protrusion 24 includes an attachment portion 45 into which the component 44 is inserted. The attachment portion 45 is an opening (i.e., a through hole or a hole), a cutout portion, or other structures provided in the protrusion 24. The component 44 is disposed at the attachment portion 45 and is aligned with the protrusion 24 in a direction substantially parallel to a rear surface 6b of a display 6. An example of the component 44 is an antenna, a camera, a connector, or an external connector (external I/O connector), but the component 44 is not limited to the above-mentioned example.

According to this structure, similarly to the first embodiment, it is possible to improve the protection of the display 6 and the solidity of the housing 4. In this embodiment, the electronic apparatus 31 includes the component 44 that is attached to the second portion 42 of the supporter 26 and is disposed between the second portion 42 and the rear cover 22. According to this structure, since the component 44 is arranged close to the panel 7, it is possible to reduce the thickness of the housing 4 (electronic apparatus 31).

### Sixth Embodiment

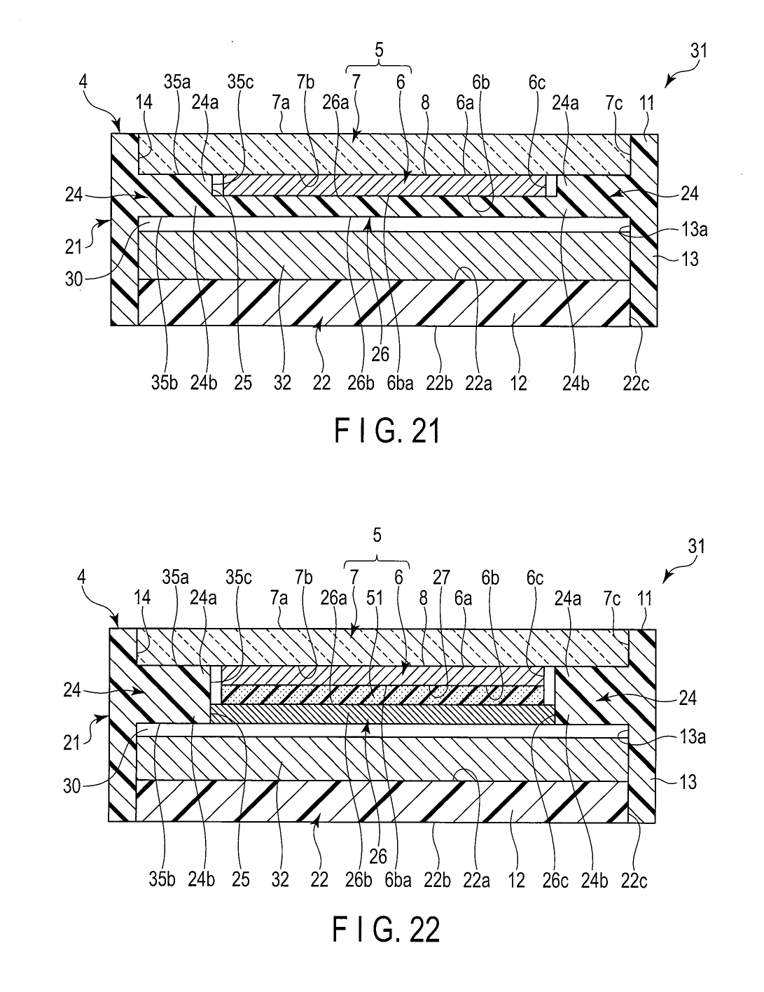

Next, an electronic apparatus 31 according to a sixth embodiment will be described with reference to FIG. 21. In the sixth embodiment, components having the same or similar functions as those in the first to fifth embodiments are denoted by the same reference numerals and the description thereof will not be repeated. Structures other than the following structures are the same as those in the second embodiment.

As shown in FIG. 21, in this embodiment, a supporter 26 is a portion of a front mask 21. The supporter 26 is provided integrally with a second portion 24b of a protrusion 24 and is connected to the second portion 24b. In this way, the supporter 26 is supported by the protrusion 24.

According to this structure, similarly to the first embodiment, it is possible to improve the protection of the display 6 and the solidity of the housing 4. In addition, in this embodiment, the supporter 26 is a portion of the front mask 21. Therefore, for example, a sheet metal member may not be provided and it is possible to reduce the manufacturing costs of the electronic apparatus 31 and improve the assemblability of the electronic apparatus 31.

### Seventh Embodiment

Next, an electronic apparatus 31 according to a seventh embodiment will be described with reference to FIG. 22. In the seventh embodiment, components having the same or similar functions as those in the first to sixth embodiments are denoted by the same reference numerals and the description thereof will not be repeated. Structures other than the following structures are the same as those in the second embodiment.

As shown in FIG. 22, in this embodiment, an elastic portion 51 (i.e., an elastic member, a buffer portion, or a buffer member) is provided between a rear surface 6b of a display 6 and a supporter 26. The elastic portion 51 is, for example, sponge, but is not limited thereto. The elastic portion 51 is, for example, an insulator and has an insulating property.

According to the electronic apparatus having the above-mentioned structure, similarly to the first embodiment, it is possible to improve the protection of the display 6 and the solidity of the housing 4. In this embodiment, the elastic portion 51 is provided between the display 6 and the supporter 26. According to this structure, for example, when the user performs an operation, the elastic portion 51 can absorb a portion of the pressing force applied to the front surface of a display unit 5. Therefore, it is possible to protect the display 6.

### Eighth Embodiment

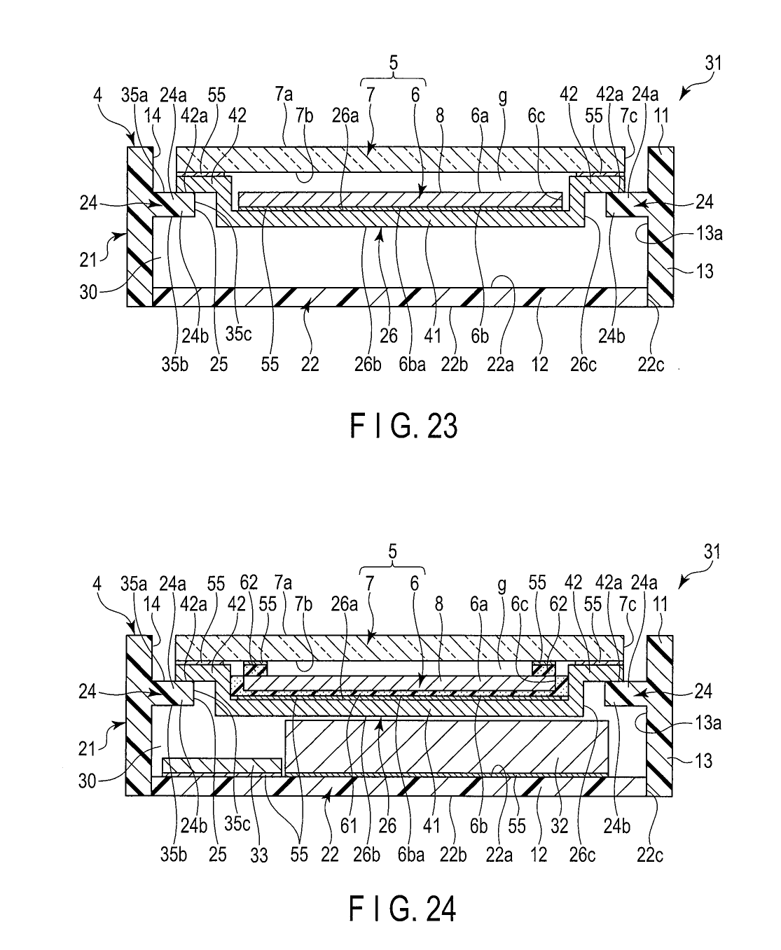

Next, an electronic apparatus 31 according to an eighth embodiment will be described with reference to FIG. 23. In the eighth embodiment, components having the same or similar functions as those in the first to seventh embodiments are denoted by the same reference numerals and the description thereof will not be repeated. Structures other than the following structures are the same as those in the fourth embodiment.

As shown in FIG. 23, in this embodiment, a display 6 is not fixed to a panel 7. The display 6 is separated from the panel 7 and is supported by a supporter 26. A gap g (e.g., air gap) is formed between the panel 7 and the display 6. An adhesive portion 55 (e.g., adhesive layer) is provided between the display 6 and the supporter 26. An example of the adhesive portion 55 is a double-sided tape. The adhesive portion 55 is also provided between the panel 7 and the supporter 26.

According to the electronic apparatus having the above-mentioned structure, similarly to the first embodiment, it is possible to improve the protection of the display 6 and the solidity of the housing 4.

### Ninth Embodiment

Next, an electronic apparatus 31 according to a ninth embodiment will be described with reference to FIG. 24. In the ninth embodiment, components having the same or similar functions as those in the first to eighth embodiments are denoted by the same reference numerals and the description thereof will not be repeated. Structures other than the following structures are the same as those in the eighth embodiment.

As shown in FIG. 24, in this embodiment, a first elastic portion 61 (i.e., an elastic member, a buffer portion, or a buffer member) is provided between a display 6 and a supporter 26. An example of the first elastic portion 61 is sponge, but the first elastic portion 61 is not limited thereto. The first elastic portion 61 includes a first portion that is provided between a rear surface 6b of the display 6 and the supporter 26 and a second portion that is provided between a side surface 6c of the display 6 and the supporter 26.

In this embodiment, in addition, a second elastic portion 62 (i.e., an elastic member, a buffer portion, or a buffer member) is provided between the display 6 and a panel 7. An example of the second elastic portion 62 is sponge, but the second elastic portion 62 is not limited thereto. The second elastic portion 62 is disposed between a front surface 6a of the circumferential end of the display 6 and a rear surface 7b of the panel 7.

According to this structure, similarly to the first embodiment, it is possible to improve the protection of the display 6 and the solidity of the housing 4. In this embodiment, the first elastic portion 61 is provided between the display 6 and the supporter 26. In addition, the second elastic portion 62 is provided between the panel 7 and the display 6. According to this structure, for example, when the user performs an operation, the first and second elastic portions 61 and 62 can absorb a portion of the pressing force applied to the front surface of a display unit 5. Therefore, it is possible to protect the display 6.

### Tenth Embodiment

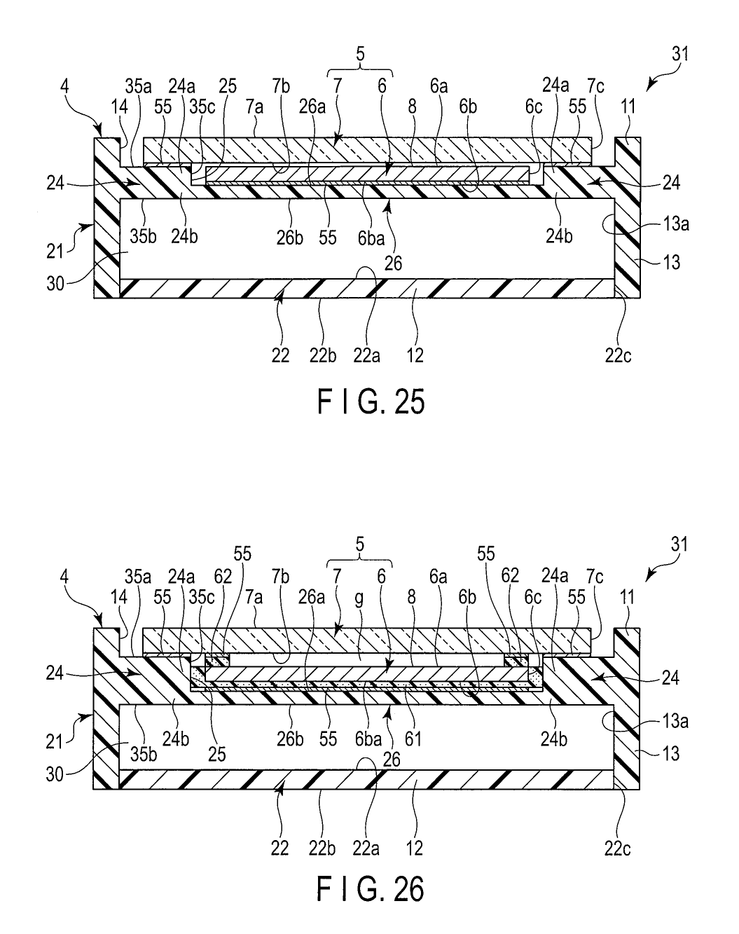

Next, an electronic apparatus 31 according to a tenth embodiment will be described with reference to FIG. 25. In the tenth embodiment, components having the same or similar functions as those in the first to ninth embodiments are denoted by the same reference numerals and the description thereof will not be repeated. Structures other than the following structures are the same as those in the sixth embodiment.

As shown in FIG. 25, in this embodiment, a display 6 is not fixed to a panel 7. The display 6 is separated from the panel 7 and is supported by a supporter 26. A gap g (e.g., air gap) is formed between the panel 7 and the display 6.

According to this structure, similarly to the first and sixth embodiments, it is possible to improve the protection of the display 6 and the solidity of the housing 4.

### Eleventh Embodiment

Next, an electronic apparatus 31 according to an eleventh embodiment will be described with reference to FIG. 26. In the tenth embodiment, components having the same or similar functions as those in the first to tenth embodiments are denoted by the same reference numerals and the description thereof will not be repeated. Structures other than the following structures are the same as those in the sixth embodiment.

As shown in FIG. 26, in this embodiment, similarly to the ninth embodiment, a first elastic portion 61 (i.e., an elastic member, a buffer portion, or a buffer member) is provided between a display 6 and a supporter 26. An example of the first elastic portion 61 is sponge, but the first elastic portion 61 is not limited thereto. The first elastic portion 61 includes a first portion that is provided between a rear surface 6b of the display 6 and the supporter 26 and a second portion that is provided between a side surface 6c of the display 6 and the supporter 26.

In this embodiment, in addition, a second elastic portion 62 (i.e., an elastic member, a buffer portion, or a buffer member) is provided between the display 6 and a panel 7. An example of the second elastic portion 62 is sponge, but the second elastic portion 62 is not limited thereto. The second elastic portion 62 is disposed between a front surface 6a of the circumferential end of the display 6 and a rear surface 7b of the panel 7.

Next, some modifications of the display unit 5 which can be applied to each of the first to eleventh embodiments will be described. A first example of the display unit 5 includes a glass panel, a touch panel, a translucent adhesive portion, and a liquid crystal display. In a second example of the display unit 5, the glass panel of the display unit 5 according to the first example is changed to a plastic panel and the liquid crystal display is changed to an organic EL display. That is, the display unit 5 according to the second example includes a plastic panel, a touch panel, a translucent adhesive portion, and an organic EL display.

A display unit 5 according to a third example includes a plastic panel provided with a touch sensor, a translucent adhesive portion, and an organic EL display. A display unit 5 according to a fourth example is an in-cell touch panel type without the glass panel of the display unit 5 according to the first example. The display unit 5 according to the fourth example includes an organic EL display provided with a touch sensor.

According to this structure, similarly to the first and ninth embodiments, it is possible to improve the protection of the display 6 and the solidity of the housing 4.

The embodiments are not limited to the above-described embodiments, but the components according to the above-described embodiments may be changed without departing from the scope and spirit of the invention. In addition, a plurality of components according to the above-described embodiments may be appropriately combined with each other to form various structures. For example, some of the components according to the above-described embodiments may be removed. Components according to different embodiments may be appropriately combined with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A television comprising:
a display comprising a front surface, a rear surface, and a side surface;
a rear cover configured to cover the rear surface of the display;
a supporter between the display and the rear cover, the supporter configured to support at least a central portion of the rear surface of the display; and
a front mask exposed comprising
a front wall comprising an opening configured to expose the front surface of the display,
a side wall extending from the front wall toward the rear cover, the side wall configured to cover a side surface of the rear cover, and
a protrusion protruding from an inner surface of the side wall, the protrusion configured to support the display and the supporter, the protrusion comprising
a first portion configured to face the side surface of the display, and
a second portion protruding from the first portion toward the rear cover, the second portion closer to the rear cover than the rear surface of the display to the rear cover.

2. The television of claim 1,
wherein the second portion is configured to support the supporter.

3. The television of claim 1,
wherein the protrusion is annular shaped along the inner surface of the side wall, and
at least a part of the supporter is in an opening defined by the protrusion.

4. The television of claim 1, further comprising:
an elastic portion between the display and the supporter.

5. The television of claim 1,
wherein the supporter is a portion of the front mask, and integral with the second portion.

6. An electronic apparatus comprising:
a display comprising a front surface, a rear surface, and a side surface;
a rear cover configured to cover the rear surface of the display;
a supporter between the display and the rear cover, the supporter configured to support the rear surface of the display; and
a front mask comprising
a front wall comprising an opening configured to expose the front surface of the display,
a side wall extending from the front wall toward the rear cover, and
a protrusion protruding from an inner surface of the side wall, the protrusion configured to support the display, the protrusion comprising a portion closer to the rear cover than at least a part of the supporter.

7. The electronic apparatus of claim 6,
wherein the protrusion is annular shaped along the inner surface of the side wall, and
at least a part of the supporter is in an opening defined by the protrusion.

8. The electronic apparatus of claim 6,
wherein the display comprises a display screen and a light-transmitting panel facing the display screen, and
the supporter comprises an engaging portion between the panel and the protrusion.

9. The electronic apparatus of claim 8, further comprising:
a component attached to the engaging portion, the component between the engaging portion and the rear cover.

10. An electronic apparatus comprising:
a display comprising a front surface, a rear surface, and a side surface;
a rear cover configured to cover the rear surface of the display;
a supporter between the display and the rear cover, the supporter configured to support the rear surface of the display, the supporter comprising a side surface; and
a front mask exposed, the front mask comprising
an opening configured to expose the front surface of the display, and
a protrusion configured to support the display, the protrusion comprising
a first portion configured to face the side surface of the display, and
a second portion configured to face the side surface of the supporter.
